(19) United States
(12) Patent Application Publication
(10) Pub. No.: US 2025/0003069 A1
(43) Pub. Date: Jan. 2, 2025

(54) DRY PROCESS TOOL WITH ADJUSTABLE FLOW VALVE

(71) Applicant: Lam Research Corporation, Fremont, CA (US)

(72) Inventors: Jon Garret JUDGE, Tigard, OR (US); Nick Ray LINEBARGER, Jr., Beaverton, OR (US); Daniel BOATRIGHT, Estacada, OR (US)

(21) Appl. No.: 18/709,590

(22) PCT Filed: Nov. 19, 2022
(86) PCT No.: PCT/US2022/080198

§ 371 Date: May 13, 2024

Related U.S. Application Data
(60) Provisional application No. 63/264,780, filed on Dec. 1, 2021.

(51) Int. Cl. C23C 16/455; C23C 16/44; C23C 16/52

(52) U.S. Cl. CPC C23C 16/45544; C23C 16/4402; C23C 16/45512; C23C 16/52

(57) ABSTRACT

A system for a dry process tool comprises one or more processing chambers, two or more processing stations being positioned within the one or more processing chambers; and a first gas source. A common manifold is coupled to the first gas source via at least a first mass flow controller. The common manifold fluidly couples the first gas source to each processing station of the two or more processing stations via a corresponding flow path. Each corresponding flow path comprises an adjustable flow valve.

### BACKGROUND

Dry process tools, such as deposition tools and etching tools, use carefully metered combinations of processing gases to deposit material onto or remove material from the surface of a substrate. Some tools may include multiple processing stations that share common processing gas sources. Such an arrangement may allow for parallel processing of multiple substrates under consistent conditions.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to dry process tools comprising adjustable flow valves. One example provides a system for a dry process tool comprising one or more processing chambers. Two or more processing stations are positioned within the one or more processing chambers. The system further comprises a first gas source. A common manifold is coupled to the first gas source via at least a first mass flow controller. The common manifold fluidly couples the first gas source to each processing station of the two or more processing stations via a corresponding flow path. Each corresponding flow path comprises an adjustable flow valve.

In some such examples each adjustable flow valve is adjustable to have a highest valve flow coefficient within the corresponding flow path.

In some such examples, one or more of the corresponding flow paths additionally or alternatively comprises a fixed orifice positioned in parallel with the adjustable flow valve.

In some such examples, each corresponding flow path is additionally or alternatively coupled to the common manifold via a flexible gas line, and each flow path additionally or alternatively comprises one or more components that are configured to be movable relative to a processing chamber of a respective processing station.

In some such examples, each flow path additionally or alternatively comprises an on/off flow valve upstream of the adjustable flow valve.

In some such examples, each flow path additionally or alternatively comprises a filter upstream of the on/off flow valve.

In some such examples, the system additionally or alternatively comprises a second gas source connected to the common manifold via a second mass flow controller.

In some such examples, the system additionally or alternatively comprises, for each processing station, a mixer positioned within the flow path upstream of the processing station. The mixer for each processing station is additionally or alternatively coupled via a second corresponding flow path to a second common manifold. The second common manifold is coupled to a second gas source. The second gas source provides a different gas composition than the first gas source.

In some such examples, the second corresponding flow path additionally or alternatively comprises an on/off flow valve in series with one or more of a fixed orifice or a second adjustable flow valve.

In some such examples, the one or more processing chambers additionally or alternatively comprise a plurality of processing chambers. Additionally or alternatively, each processing station of the two or more processing stations is positioned within a separate processing chamber of the plurality of processing chambers.

Additionally or alternatively, in some such examples, at least two of the two or more processing stations are positioned within a shared processing chamber of the one or more processing chambers.

In some such examples, the dry process tool additionally or alternatively comprises a chemical vapor deposition tool.

In some such examples, the dry process tool additionally or alternatively comprises an atomic layer deposition tool.

In some such examples, the dry process tool additionally or alternatively comprises a dry-etching tool.

In some such examples, the adjustable flow valve additionally or alternatively comprises an automated valve.

Another example provides a method for calibrating a multi-station processing system. The method comprises setting a chamber pressure of a common gas source to a calibration gas pressure. For each station of the multi-station processing system coupled to the common gas source, the method comprises closing gas flow to one or more other stations and flowing gas from the common gas source to a station being adjusted. An upstream gas pressure is sensed at the gas source. When the upstream gas pressure is not within a threshold difference from a predetermined gas pressure, then an adjustable valve in a flow path to the station being adjusted is adjusted to set the upstream gas pressure to a pressure within a threshold difference from the predetermined gas pressure.

In some such examples, calibrating the multi-station processing system is additionally or alternatively performed in response to a changed consumable component in one or more stations.

Another example provides a method for calibrating a multi-station processing system. The method comprises balancing gas flow for at least a first station and a second station of the multi-station processing system by adjusting a first adjustable valve in a first flow path of the first station and adjusting a second adjustable valve in a second flow path of the second station. A compensatable hardware disparity is sensed in the first station. Gas flow for the first station is adjusted by adjusting a setting of the first adjustable valve in the flow path of the first station. A setting of the second adjustable valve is maintained.

In some such examples, adjusting gas flow for the first station additionally or alternatively comprises increasing gas flow by increasing a size of an aperture of the first adjustable valve.

In some such examples, adjusting gas flow for the first station additionally or alternatively comprises decreasing gas flow by decreasing a size of an aperture of the first adjustable valve.

Another example provides a system comprising one or more processing chambers, two or more processing stations being positioned within the one or more processing chambers, and a gas source configured to provide a processing gas to the two or more processing stations. For each processing station, a corresponding flow path comprises a corresponding mass flow controller located between the gas source and the processing station, the corresponding mass flow controller configured to control flow of the processing gas to the processing chamber.

In some such examples, the processing gas additionally or alternatively comprises two or more component gases, the component gases comprising one or more reactive gases and one or more carrier gases.

In some such examples, the gas source is additionally or alternatively configured to provide two or more gases, and further comprising a mixer positioned between the gas source and the one or more processing chambers, the mixer being configured to mix the two or more gases, and the corresponding mass flow controller for each processing station being located between the mixer and the processing station.

In some such examples, each gas of the two or more gases is additionally or alternatively connected to the mixer by a second corresponding mass flow controller between the gas source and the mixer.

In some such examples, each carrier gas is additionally or alternatively coupled to a carrier gas manifold via a corresponding carrier gas mas flow controller, the carrier gas manifold being configured to divide carrier gas flow into carrier gas lines for each processing station.

In some such examples, each corresponding flow path additionally or alternatively comprises a corresponding mixer to mix the one or more reactive gases with the one or more carrier gases.

Another example provides a system comprising one or more processing chambers, two or more processing stations being positioned within the one or more processing chambers, and two or more gas sources, each gas source coupled to a common mixer via a respective mass flow controller. A flow ratio controller divides flow from the common mixer to each processing station of the two or more processing stations.

In some such examples, a carrier gas source is additionally or alternatively coupled to a gas manifold via a dedicated mass flow controller, the gas manifold dividing carrier gas flow into carrier gas lines for each processing station. For each processing station, a flow path comprises a mixer, the mixer configured to receive an output of the common mixer and a carrier gas line, and further configured to direct a combined gas flow to the respective processing station.

In some such examples, the two or more gas sources additionally or alternatively comprise one or more reactive gas sources and one or more carrier gas sources.

### BRIEF DESCRIPTION OF THE DRAWINGS

FIG. 1 schematically shows an example dry process tool for a processing a substrate.

FIG. 2 schematically shows an example multi-station process tool.

FIG. 3 schematically shows an example cluster of process tools.

FIG. 4 schematically shows an example gas distribution system for a dry process tool comprising a gas flow path with an adjustable flow valve.

FIG. 5 schematically shows an example gas distribution system for a dry process tool comprising a gas flow path with an adjustable flow valve in parallel with a fixed orifice.

FIG. 6 shows a flow diagram illustrating an example method for balancing gas flow for a multi-station process tool comprising adjustable flow valves within each gas flow path.

FIG. 7 shows a flow diagram illustrating an example method for calibrating a multi-station process tool comprising adjustable flow valves.

FIG. 8-9 schematically show example multi-station process tools comprising mass flow controllers to control gas flow into a plurality of processing stations.

FIGS. 10-11 schematically show example multi-station process tools comprising mass flow controllers and flow ratio controllers to control gas flow into a plurality of processing stations.

FIG. 12 schematically shows another example multi-station process tool comprising mass flow controllers to control gas flow into a plurality of processing stations.

FIG. 13 schematically depicts an example computing environment.

### DETAILED DESCRIPTION

Dry process tools, such as chemical vapor deposition tools and atomic layer deposition tools, may be used to deposit thin films on a substrate using gas phase species. Other dry process tools, such as dry etching tools, use gas phase species to remove material from a substrate.

Multiple processing stations may be incorporated into a single dry process tool. This arrangement allows for sharing of resources, such as processing chambers, robotics, and gas sources.

The processing stations of a multi-station tool can be operated to perform a same process on multiple wafers. When used in this manner, careful balancing of processing gas flows across the stations helps to maintain wafer-to-wafer film consistency. One method to balance flows across stations of a multi-station tool involves the use of precision orifices in the gas flow path for delivering gas to each station. Each fixed orifice is designed to have a dominant valve flow coefficient (Cv) for the pathway. However, each gas flow path may comprise numerous other components, such as valves, filters, mixers, and conduits. The sum of the tolerances for all components in a gas flow path may cause differences in gas flow between stations to be outside of a desired range (e.g., desired dimensional tolerance range), even where differences between the precision orifices themselves are within the desired range.

Thus, various methods can be used to balance the gas flows between stations. One method of performing such additional balancing is to manually swap gas flow path components. Components that can be swapped include orifices, other valves, mixers, conduits, and/or other components. However, component swapping is costly and time-consuming. Further, the component swapping must be done each time a component is replaced in a gas flow path. Another method is to use heated gas lines to enable tuning of gas flow. However, heated gas lines can be costly to install. Further, heated gas lines may not provide for much practical tuning range.

Thus, examples are disclosed that relate to providing for accurate adjustment of gas flow rates to stations in multi-station processing tools. In some examples, the gas flow path to each station comprises an adjustable valve. In other examples, various arrangements of flow controllers, such as mass flow controllers and/or flow ratio controllers, are provided to adjust gas flows to each station.

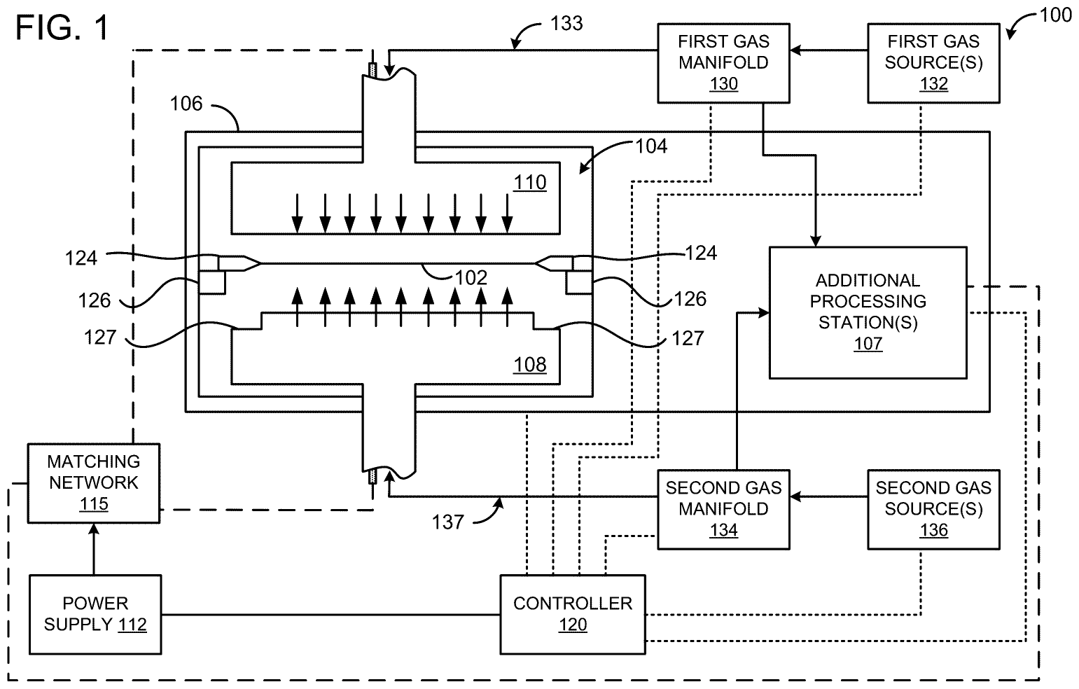

Prior to discussing these examples, an example dry process tool 100 is described with reference to FIG. 1. Dry process tool 100 is configured to process a substrate 102. The term “substrate” is used herein to refer to any workpiece that can be processed in the disclosed example tools. Examples include semiconductor substrates, such as silicon wafers. The terms “front” and “back” are used herein to describe opposite sides of a substrate. In the case of semiconductor wafers, the front side is where devices are fabricated and where a majority of processing steps are performed.

In some examples, dry process tool 100 may use a flow of gas phase precursors to deposit thin films of materials on a surface of substrate 102. In other examples, dry process tool 100 may use gas phase species to remove material from the surface of substrate 102. In some such processes, a plasma may be used to generate reactive species for deposition or etching.

Dry process tool 100 comprises one or more processing stations 104 at which a substrate 102 can be treated. Each processing station 104 is positioned within a processing chamber 106. In some examples, two or more processing stations 104 may be in a same processing chamber 106. This is illustrated in FIG. 1 by additional processing station(s) 107.

Dry process tool 100 is configured to allow processing to be selectively performed on a substrate front side or a substrate back side. A pedestal 108 is provided to support substrate 102 when a front side of substrate 102 is being processed. In some examples, the pedestal may include a heat source, such as a resistive heater (not shown). As dry process tool 100 is configured for both front side and back side processing, pedestal 108 is also configured to distribute gases toward a back side of a substrate. Pedestal 108 thus also is referred to herein as a showerhead pedestal 108. In other examples, a dry process tool may comprise a pedestal or other substrate holder without showerhead capabilities.

Dry process tool 100 further comprises a showerhead 110 positioned facing the pedestal 108. Showerhead 110 is configured to distribute reactant or inert gases toward a substrate front side, depending upon a process being performed. In some examples, showerhead 110 is electrically coupled to a radio frequency (RF) power supply 112 via an RF matching network 115. Power supply 112 may be controlled by controller 120. In other examples, RF power may be provided to showerhead pedestal 108 instead of showerhead 110. In further examples, RF power can be selectively provided to either of pedestal 108 or showerhead 110.

Substrate 102 is positioned on a carrier ring 124 that can be mechanically moved to other process stations. In FIG. 1, substrate 102 is positioned for backside processing. As such, carrier ring 124 is positioned on supports 126 that are configured to hold substrate 102 a selected distance above showerhead pedestal 108. In this configuration, reactant gases can be distributed toward a back side of substrate 102 via showerhead pedestal 108, while inert gases can be distributed toward a front side of substrate 102 via showerhead 110 (e.g. to prevent reactant gases directed to the back side from reaching the front side). In some examples, each support 126 can take the form of a mechanically moveable device, such as a paddle or spider fork. In other examples, each support 126 can take the form of a spacer coupled with showerhead pedestal 108. Such spacers can be removed from showerhead pedestal 108 to allow a substrate to be placed on showerhead pedestal 108 for front side processing.

When the front side of substrate 102 is being processed, substrate 102 is positioned on showerhead pedestal 108, and carrier ring 124 rests on a carrier ring support region 127 of the pedestal 108. An end effector (not shown) can be used to place the substrate 102 and carrier ring 124 on pedestal 108 for front side processing, or on supports 126 for back side processing.

In some examples, at least a portion of processing station 104 may move relative to processing chamber 106. For example, dry process tool 100 may comprise a motor-driven bellows (not shown) to move showerhead pedestal 108 vertically. The movement of showerhead pedestal 108 can be facilitated by one or more flexible gas lines (not shown in FIG. 1) that are coupled to gas flow path components leading to pedestal 108.

The dry process tool 100 further comprises a first gas manifold 130 that is connected to a first gas source(s) 132. The first gas source(s) 132 may comprise one or more reactant gases and/or one or more non-reactant carrier gases.

Controller 120 controls the delivery of gas from first gas source(s) 132 via first gas manifold 130 to showerhead 110 via gas flow path 133. As a specific example, when deposition is targeted for the back side of substrate 102, an inert gas flow is directed over the front side of substrate 102 via the showerhead 110. As mentioned above, the inert gas flow can push reactant gas away from the substrate front side, facilitating back side processing.

In various examples, reactant gases may be premixed before introduction into chamber 106, or introduced separately into chamber 106. Process gases exit processing chamber 106 via an outlet. A vacuum pumping system is employed to draw process gases out and maintain a suitably low pressure within the reactor.

FIG. 1 also shows a second gas manifold 134 configured to provide gases to showerhead pedestal 108. Second gas source(s) 136 are shown coupled to a second gas manifold 134. Second gas source(s) 136 are configured to provide one or more reactant and/or inert gases to showerhead pedestal 108 via gas flow path 137. The composition of gases of second gas source(s) 136 may be different than first gas source(s) 132.

Additional processing station(s) 107 also receive gases from first gas manifold 130 and second gas manifold 134. Additional processing station(s) 107 further may receive power from RF power supply 112 via RF matching network 115. Additional processing station(s) 107 also may exchange signals with, and be controlled by, controller 120.

Controller 120 comprises one or more logic devices, one or more memory devices, and one or more interfaces. Controller 120 may be employed to control actuators in the system based in part on sensed values. For example, controller 120 may control one or more valves, filter heaters, pumps, and other devices based on sensed values and other control parameters. Controller 120 may receive the sensed values from sensors, such as pressure manometers, flow meters, temperature sensors, mass flow control modules, position sensors, etc.

Controller 120 is configured to operate dry process tool 100 by executing process input and control for specific recipes. Controller 120 may be configured to execute computer programs comprising sets of instructions for controlling process timing, delivery system temperature, pressure differentials across the filters, valve states, mixture of gases, chamber pressure, chamber temperature, substrate temperature, radio frequency (RF) power levels, pedestal position, substrate height above pedestal, and/or any other suitable variables.

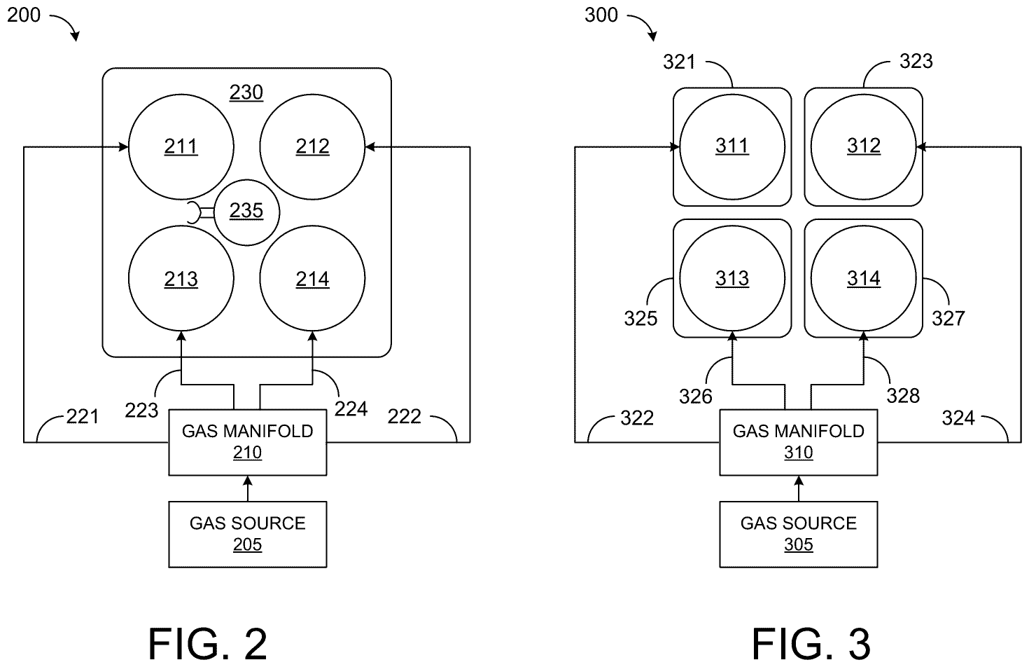

As mentioned above, multiple processing stations may share one or more common gas sources. FIG. 2 shows an example gas distribution system for a multi-station process tool 200. For simplicity, a single gas source 205 is shown coupled to a single gas manifold 210. However, as described in more detail below, a plurality of gas sources may be coupled to a gas manifold. Further, a dry processing tool may comprise a plurality of gas manifolds, each coupled to one or more gas sources.

Multi-station process tool 200 comprises processing station 1 211, processing station 2 212, processing station 3 213, and processing station 4 214. Although four processing stations are shown, in other examples, multi-station process tool 200 may comprise two, three, or more than four processing stations. Multi-station process tool 200 may be configured for any suitable type of process. In some examples, multi-station process tool is configured for deposition processes, such as atomic layer deposition and/or chemical vapor deposition. In other examples, multi-station processing tool is configured for dry etching processes. Further, multi-station process tool 200 may be configured for front side and back side processing, or front side processing only. Dry process tool 100 is an example implementation of each of processing stations 1-4 (211-214).

Each processing station is coupled to gas source 205 via gas manifold 210 and a dedicated flow path. Processing station 1 211 receives gases from gas manifold 210 via flow path 221. Processing station 2 212 receives gases from gas manifold 210 via flow path 222. Processing station 3 213 receives gases from gas manifold 210 via flow path 223. Processing station 4 214 receives gases from gas manifold 210 via flow path 224. In this example, processing stations 211-214 are all positioned within a common processing chamber 230. Using a common processing chamber allows for multi-station process tool 200 to share resources across processing stations 211-214. For example, a robot 235 may be employed within common processing chamber 230 to load and unload substrates from one processing station to the next in a sequential processing routine. Other resources, such as RF power, vacuum, load locks, inlets, outlets, etc. can also be shared.

In this way, multiple substrates may be processed simultaneously, with limited pump-downs. A variety of different processes may be performed. For example, in a deposition context, four substrates can be run together to deposit films of a full thickness on the four substrates in parallel. Also, four substrates can be rotated between stations to deposit a quarter of a total film thickness at a time at each station. As another example, two substrates can be run per station, with each station depositing half a desired thickness.

FIG. 3 shows another example system in which multiple processing stations share a common gas source. More specifically, FIG. 3 shows a process tool cluster 300. Process tool cluster 300 is shown with a single gas source 305 coupled to a single gas manifold 310. However, other configurations may utilize more than one gas source and/or more than one manifold.

Process tool cluster 300 comprises four processing tools each having a single station. The tools comprise processing stations 311, 312, 313, and 314. In other examples, a process tool cluster may comprise more or fewer processing tools. Process tool 100 is an example implementation of each processing station 311-314. In other examples, processing stations 311-314 may have any other suitable configuration.

Each processing station 311, 312, 313, 314 is coupled to gas source 305 via gas manifold 310 and a corresponding flow path. In this example, each processing station is housed within a separate processing chamber. Processing station 311 is positioned within processing chamber 321, and receives gases from gas manifold 310 via flow path 322. Processing station 312 is positioned within processing chamber 323, and receives gases from gas manifold 310 via flow path 324. Processing station 313 is positioned within processing chamber 325, and receives gases from gas manifold 310 via flow path 326. Processing station 314 is positioned within processing chamber 327, and receives gases from gas manifold 310 via flow path 328. By connecting and balancing each processing station to the same gas source 305, consistency across processing stations may be achieved, and resources may be pooled. In some examples, each of one or more tools of process tool cluster 300 may comprise multiple processing stations.

As mentioned above, gas flow paths for dry process tools may comprise a precision fixed orifice to help achieve consistent gas flows to each processing station from a common manifold. However, a sum of the tolerances for all components in a gas flow path may cause differences between stations to be outside of a desired dimensional tolerance range, even where differences between the precision orifices themselves are within the desired dimensional tolerance range. Further, placement of such components upstream of a splitting of flow paths to different processing stations may not be possible or practical for multi-station tools where components of the gas flow path move independently (e.g. a pedestal with vertical movement capabilities).

Thus, to overcome such problems with fixed orifices, a variable flow valve comprising an adjustable Cv can be provided in the flow path to each processing station. Each adjustable valve can be adjusted independently, and can be re-calibrated if a station ages or wears differently than the other stations in the tool.

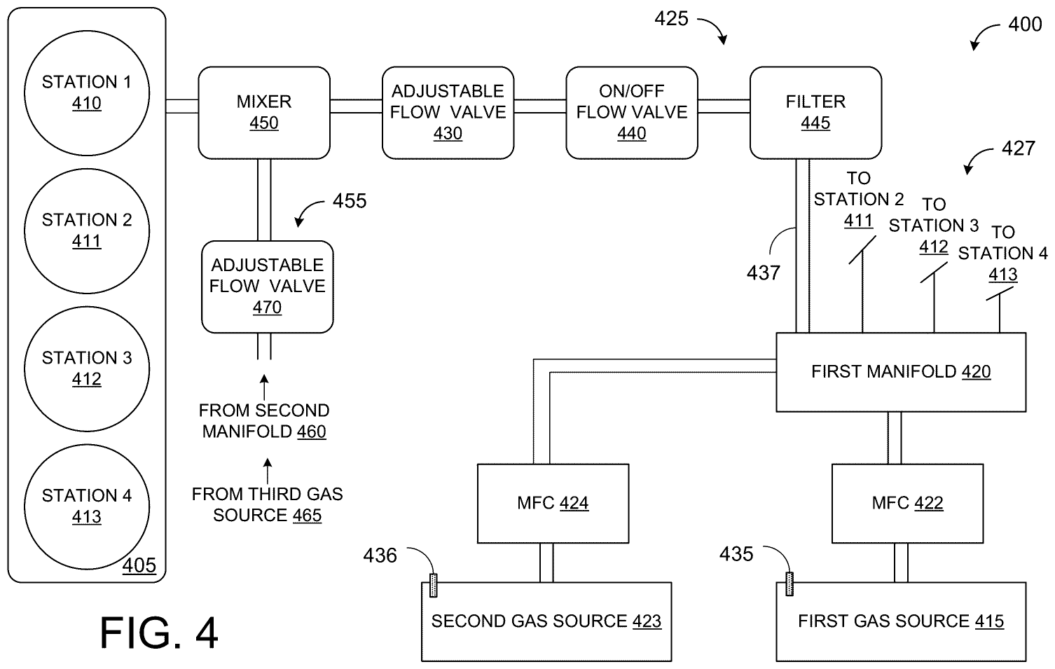

FIG. 4 schematically shows an example gas distribution system 400 for a dry process tool. In some examples, dry process tool may comprise a chemical vapor deposition tool, an atomic layer deposition tool, or a dry-etching tool. In other examples, the dry process tool may comprise any other suitable tool that utilizes balanced flows of gases to multiple processing stations.

System 400 comprises one or more processing chambers 405 and two or more processing stations (four processing stations 410, 411, 412, 413 are shown here) positioned within the one or more processing chambers. For simplicity, only gas flow path components of a first processing station 1 410 are depicted in detail. However, gas flow paths for other processing stations may have similar components. While four processing stations are shown in this example, a gas distribution system 400 be configured for two, three, or more than four processing stations in other examples. In other examples, one or more processing stations may be positioned within processing chamber other than processing chamber 405.

System 400 further comprises a first gas source 415. A first manifold 420 is coupled to first gas source 415 via at least a first mass flow controller (MFC) 422. MFC 422 comprises at least an inlet port, an outlet port, a mass flow sensor, and a proportional control valve. The proportional control valve may be adjusted to control flow of gases based on measurements generated by the mass flow sensor. An optional second gas source 423 is connected to first manifold 420 by a second mass flow controller 424. One or more further gas sources (not shown) may be connected to first manifold 420 in other examples.

First manifold 420 fluidly couples first gas source 415 and second gas source 423 to first processing station 1 410 via a first flow path 425. The term “fluidly couples” indicates that gas can flow between components along a gas flow path. First manifold 420 also fluidly couples first gas source 415 and second gas source 423 to each additional processing station (411, 412, 413) via other corresponding flow paths, collectively indicated as flow paths 427.

Each flow path comprises an adjustable flow valve. This is illustrated for flow path 425 as adjustable flow valve 430. Adjustable flow valve 430 can be adjusted to allow gas flow to process station 410 across a suitable range of Cv values. As will be described further herein, in some examples, each adjustable flow valve may be adjusted to a different Cv, so as to balance desired flows across the multiple stations of system 400. Such an adjustable valve may provide for a greater range of tuning of gas flows than methods such as heated gas lines. Further, adjustable flow valves may provide for faster tuning than the swapping of components in a gas flow path.

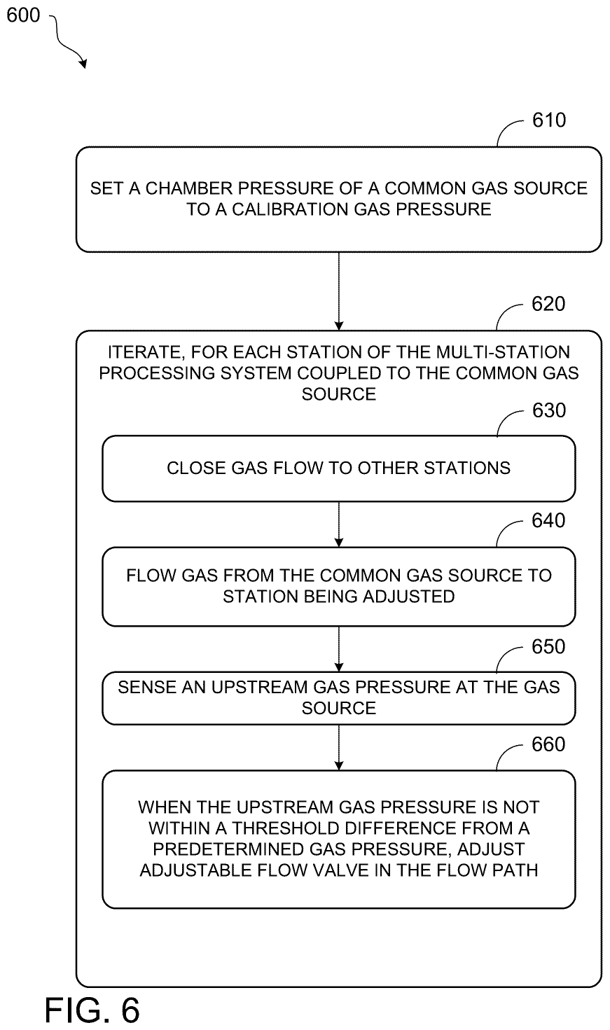

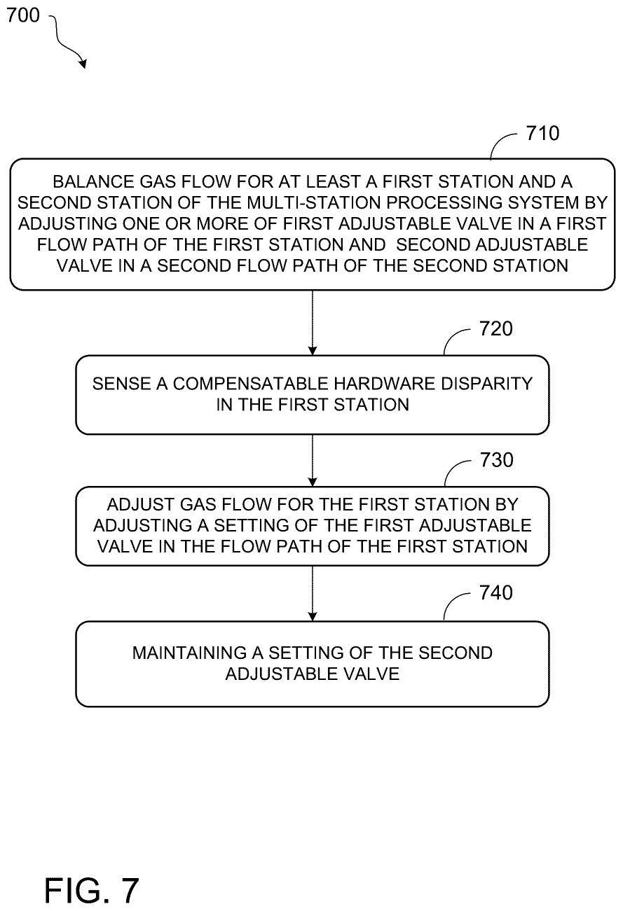

In some examples, adjustable flow valve 430 may comprise an automated valve. Such a valve may adjust an internal aperture based on signals received from a controller in response to the controller recognizing a change in upstream gas pressure. For example, first gas source 415 may comprise one or more manometers 435 configured to output a gas pressure value. As will be described further herein and with regard to FIGS. 6 and 7, this gas pressure value may be used to calibrate adjustable flow valve 430. Additionally or alternatively, adjustable flow valve 430 may be manually adjustable. Second gas source 423 may also comprise one or more manometers 436.

In some examples, flow path 425 is coupled to first manifold 420 via a flexible gas line 437. Similarly, each flow path to station 411, station 412 and station 413 also may include a flexible gas line. A flexible gas line 437 can be used where flow path 425 comprises one or more components that are configured to be movable independent of similar components of other processing stations. On example of a moveable component is as a vertically adjustable showerhead pedestal. Flow path 425 further comprises an on/off flow valve 440 upstream of adjustable flow valve 430 to allow gas flow to processing station 1 410 to be turned off. When in an “on” state, on/off flow valve 440 may have a smaller orifice than the largest allowable orifice through adjustable flow valve 430. Flow path 425 may further comprise one or more filters 445 upstream of on/off flow valve 440. Filters 445 remove airborne molecular contaminants based on size, adsorption characteristics, or other properties of molecules. Filters 445 may be consumable components, and may be replaced as needed.

System 400 further comprises a mixer 450 positioned within flow path 425 upstream of processing station 1 410. Mixer 450 may serve to blend multiple gases into a suitably homogenous mixture prior to metering flow of the mixture into processing station 1 410. Mixers also may be used in gas flow paths for station 2 411, station 3 412, and station 4 413. Mixer 450 may be coupled to a second manifold 460, via a second flow path 455. Second manifold 460 may be coupled to a third gas source 465. Third gas source 465 provides a different gas composition than first gas source 415 or second gas source 423. In this way, reactive gases may be kept separate as long as possible before entering processing station 1 410. For example, first gas source 415 may comprise silane type gases, while third gas source 465 may comprise oxidizing gases. Second manifold 460 may be coupled to each processing station of system 400, or each processing station may be coupled to a separate second gas source via a dedicated manifold, so that different gas compositions may be used at each processing station.

Each component within second flow path 425 has an associated dimensional tolerance. As these flow paths come together at mixer 450, in some examples an adjustable valve 470 may be positioned within second flow path 455 to allow flow rates to be adjusted to compensate for such tolerances.

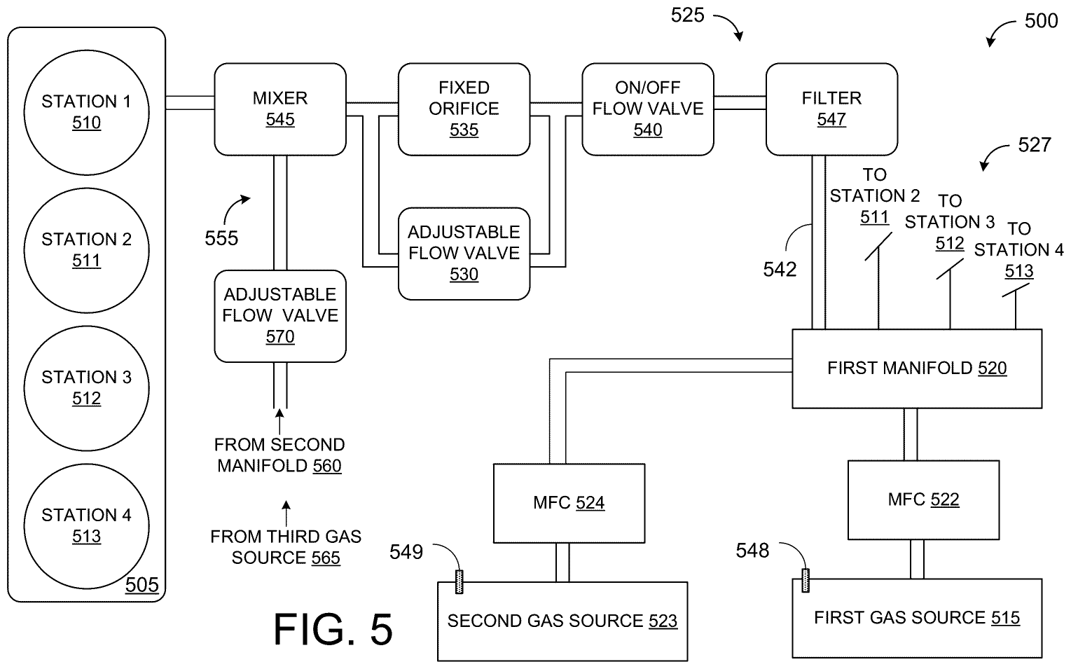

In some examples, a single adjustable flow valve may not allow sufficient Cv for high-flow processes. In such examples, an adjustable flow valve may be positioned in parallel with a fixed orifice within the corresponding flow path. FIG. 5 shows an example gas distribution system 500 for a dry-process tool having an example of a fixed orifice and adjustable valve in parallel. System 500 comprises one or more processing chambers 505 and two or more processing stations (four processing stations 510, 511, 512, 513 are shown here) positioned within the one or more processing chambers. System 500 further comprises a first gas source 515 coupled to a first manifold 520 via at least a first MFC 522. System 500 further comprises an optional second gas source 523 connected to first manifold 520 by a second mass flow controller 524. In some examples, a gas distribution system may have additional gases connected to the first manifold.

First manifold 520 fluidly couples first gas source 515 and second gas source 523 to first processing station 1 510 via a first flow path 525. First manifold 520 also fluidly couples first gas source 515 and second gas source 523 to each additional processing station (511, 512, 513) via other corresponding flow paths, collectively indicated as flow paths 527.

Flow path 525 comprises an adjustable flow valve 530 in parallel with a fixed orifice 535 positioned between on/off flow valve 540 and mixer 545. Fixed orifice 535 may be any suitable type of orifice, such as metal or ceramic (e.g. pressed sapphire).

Fixed orifice 535 may be configured as a high-flow orifice, and thus may comprise a larger orifice than adjustable flow valve. For example, fixed orifice 535 may be configured to allow for example, 90 units of gas flow, while adjustable flow valve 530 may be adjustable to allow between 5 and 15 units of gas flow, allowing a target range of 95-105 units of gas flow. In this configuration, adjustable flow valve 530 is used to fine-tune the flow rate and change the resistance flow balance. In other examples, adjustable flow valve 530 may have a larger orifice than fixed orifice 535. In this way, relatively high flow rates for an application may be achieved without further increasing the aperture size of adjustable flow valve 530.

Other components of system 500 may be similar to those described with regard to system 400. For example, flow path 525 comprises one or more filters 547. First gas source 515 may comprise one or more manometers 548 configured to output a gas pressure value. Second gas source 523 may also comprise one or more manometers 549. In some examples, flow path 525 is coupled to first manifold 520 via a flexible gas line 542.

Mixer 545 may be coupled, via a second flow path 555 to a second manifold 560. Second manifold 560 may be coupled to a third gas source 565. Third gas source 565 may provide a different gas composition than first gas source 515 and second gas source 523. In some examples, an adjustable valve 570 may be positioned within second flow path 555. Additionally or alternatively, a fixed orifice (not shown) may be positioned within second flow path 555.

FIG. 6 shows an example method 600 for calibrating a multi-station processing system. Method 600 is described with reference to system 400 of FIG. 4. However, method 600 may be applied for calibrating any suitable multi-station processing system comprising adjustable flow valves, including system 500. In some examples, method 600 may be executed by a controller or control module, such as controller 120. Additionally or alternatively, one or more aspects of method 600 may be performed manually.

At 610, method 600 comprises setting a chamber pressure of a common gas source to a calibration gas pressure. For example, readings from a manometer may be used to set a desired gas pressure, such as manometer 435 for first gas source 415. The calibration gas pressure may or may not be the same as an operational gas pressure used during process execution.

Continuing at 620, method 600 iterates through a series of processes for each station of the multi-station processing system coupled to the common gas source, as follows. At 630, method 600 comprises closing gas flow to stations other than a station being adjusted. For example, in a quad station, three flow paths may be closed by shutting an on/off flow valve within the respective flow path. Additionally or alternatively, gas flow may be closed at an upstream point in the flow path for those stations.

At 640, method 600 comprises flowing gas from the common gas source to the station being adjusted. As such, one flow path for one station is opened while the remaining flow paths are closed, allowing each flow path to be calibrated sequentially. At 650, method 600 comprises sensing an upstream gas pressure at the gas source, for example, using manometer 435 within first gas source 415. In this way, a flow through the flow path to the station being adjusted may be inferred.

At 660, method 600 comprises adjusting an adjustable flow valve in the flow path when the upstream gas pressure is not within the threshold difference from a predetermined gas pressure. Method 600 may then comprise performing processes 620-660 for each additional station, adjusting each adjustable flow valve until the predetermined upstream gas pressure is reached within a tolerance. In this manner flows through all stations of the multi-station processing system can be balanced. The process may iterate two or more times to ensure that variances between stations are not compounded. For example, in examples where there are two or more flow paths feeding a mixer for a station, each flow path comprising an adjustable valve, the flow through each flow path may impact tolerance of the other flow path. Thus, additional iterative calibration can help to correct for any gas flow misbalances in such a system.

In some examples, calibrating the multi-station processing system is performed in response to a change of a consumable component in one or more stations. For example, the multi-station processing system may be calibrated each time a filter is changed. However, calibration may additionally or alternatively be performed in response to drift in station performance over time, or at any other suitable interval. Once flow is balanced, the process can also vary other parameters (e.g., mass flow controller rates, pedestal position, pressure, power) in order to make adjustments based on observed performance (e.g., refractive index (RI) in station chambers during process flow). In examples where the adjustable flow valve is automated, observed performance may be used to open or close the valve adjust flow and thus adjust performance, either during or in between calibrations. For example, the chamber pressure within each gas source can be set to a predetermined value, and the pressure delta and downstream flow may be observed and used to determine whether the pressure drop across flow paths is within a tolerance.

FIG. 7 shows an example method 700 for calibrating a multi-station processing system. Method 700 is described with regard to system 400, as described with regard to FIG. 4. However, method 700 can be applied for calibrating any suitable multi-station processing systems that comprises adjustable flow valves, such as system 500. In some examples, method 700 may be executed by a controller or control module, such as controller 120. Additionally or alternatively, one or more aspects of method 700 may be performed manually.

At 710, method 700 comprises balancing gas flow for at least a first station and a second station of the multi-station processing system by adjusting one or more of a first adjustable valve in a first flow path of the first station or a second adjustable valve in a second flow path of the second station. For example, balancing gas flow may be performed using method 600 or an equivalent such that each station of the multi-station processing system has a gas flow within a tolerance of each other station.

At 720, method 700 comprises sensing a compensatable hardware disparity in the first station. As used herein, a compensatable hardware disparity refers to a component of a process station that demonstrates a functional difference from similar componentry in other stations, and that may be compensated for using adjustments in gas flow rates. For example, an increase in RI for a substrate being processed the first station may be observed. This may, for example, be due to a pedestal being older and comprising a higher emissivity and thus radiating more heat.

At 730, method 700 comprises adjusting gas flow for the first station by adjusting a setting of the first adjustable valve in the flow path of the first station. For example, an increase in RI at the first station may be compensated for by increasing gas flow through the first adjustable valve. In other examples, adjusting gas flow for the first station may comprise decreasing gas flow by decreasing a size of an aperture of the first adjustable valve.

At 740, method 700 comprises maintaining a setting of the second adjustable valve. In this way, gas flow for the first station and second station are intentionally disbalanced to compensate for the hardware disparities. This may allow for substrates to be processed as if each station were operating the same. In some examples, if one station has a non-compensatable hardware disparity, settings for the adjustable valves in the flow paths for the other stations may be adjusted in order to attempt to balance flow despite the disparity.

In addition to, or as an alternative to, employing a variable flow valve in a flow path, flow from each separate gas source may be regulated by one or more MFCs. This allows for active gas flow adjustments to tune each station of the tool. While MFCs are calibrated to flow a specific gas, the additional MFCs may be used to fine-tune the gas flow to each individual station, rather than specifically providing a mass flow rate of a specific gas.

As an example, one or more appropriately sized MFC may be provided for each individual station to deliver individual gas flows to the station. Depending on the process being performed, each individual station MFC may tune the gas mixture flow to a corresponding station. When one MFC is provided to deliver gas flow to a corresponding station, that MFC may be turned off to stop gas flow to the corresponding station.

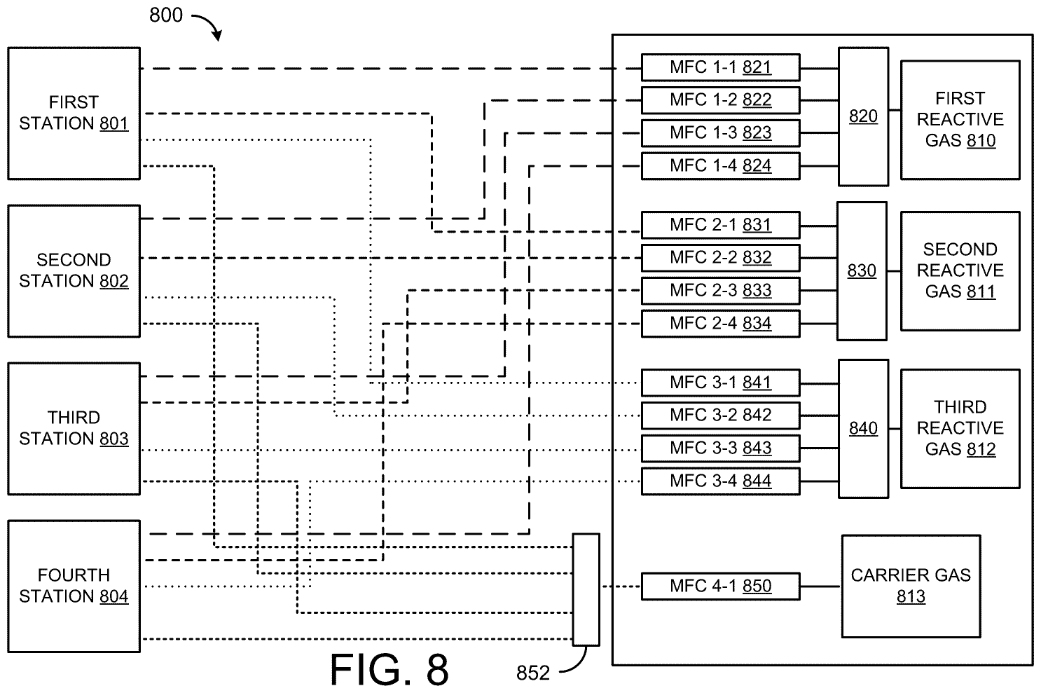

In the examples shown in FIGS. 8-12, three reactive gases and one carrier gas are mixed and flowed to four processing stations. In other examples, any other suitable set of gases may be used. The processing stations may be positioned within one processing chamber or multiple processing chambers, and may comprise one or more gas mixers that are not shown. FIGS. 8-12 depict a single gas manifold. In other examples, a second manifold may be used to provide a different gas composition, which may be mixed at or prior to each processing station. For example, the first manifold may carry reactant gases in an inert carrier gas, while the second manifold may carry an oxidizing reagent.

In some examples, a flow ratio controller (FRC) may be used to accomplish flow tuning. Further, in some examples, individual station MFCs and/or FRCs may be used only for gas(es) that need to be controlled tightly. Carrier gases may be provided further downstream without such precise control. This may simplify system design, increase flow tuning precision, and lower system cost.

Any suitable mixture of gases may be introduced to processing stations in a multi-station tool via the following gas distribution system examples. As one illustrative example, the reactive gases may comprise silane, a dopant (e.g., phosphine), and hydrogen gas, while the carrier gas may comprise nitrogen. In other examples, other gases may be used, and more or fewer than three reactive gases may be used, each regulated by one or more MFCs.

FIG. 8 schematically shows an example multi-station process tool 800 comprising mass flow controllers for each gas and for each processing station. Multi-station process tool 800 is shown comprising four processing stations-first station 801, second station 802, third station 803, and fourth station 804.

Multi-station process tool 800 further comprises gas sources 805. Gas sources 805 comprise sources for a first reactive gas 810, a second reactive gas 811, a third reactive gas 812, and a carrier gas 813. Each reactive gas is flowed to a manifold, which provides the reactive gas to a separate MFCs for each processing station. First reactive gas 810 is flowed to manifold 820. Manifold 820 splits gas flow to four MFCs: MFC 1-1 821, MFC 1-2 822, MFC 1-3 823, and MFC 1-4 824. In turn, these MFCs respectively flow first reactive gas 810 to first station 801, second station 802, third station 803, and fourth station 804, respectively.

Similarly, second reactive gas 811 is flowed to manifold 830. Manifold 830 splits gas flow to four MFCs: MFC 2-1 831, MFC 2-2 832, MFC 2-3 833, and MFC 1-4 834. In turn, the MFCs respectively flow second reactive gas 811 to first station 801, second station 802, third station 803, and fourth station 804, respectively.

Third reactive gas 812 is flowed to manifold 840. Manifold 840 splits gas flow to four MFCs: MFC 3-1 841, MFC 3-2 842, MFC 3-3 843, and MFC 3-4 844. In turn, the MFCs respectively flow third reactive gas 812 to first station 801, second station 802, third station 803, and fourth station 804, respectively. Carrier gas 813 is flowed directly to MFC 4-1 850, then to manifold 852, which flows the carrier gas to stations 801-804.

Additional valves, orifices, filters, flex lines, etc., may be present in the flow paths coupling gas sources 805 to stations 801-804, such as depicted in FIGS. 4 and 5. By using MFCs to control flow of each has to each processing station, additional control of gas flow rates may be achieved to compensate for variability in other components of the gas flow paths. Each flow path may also be provided with on/off control of each or every gas.

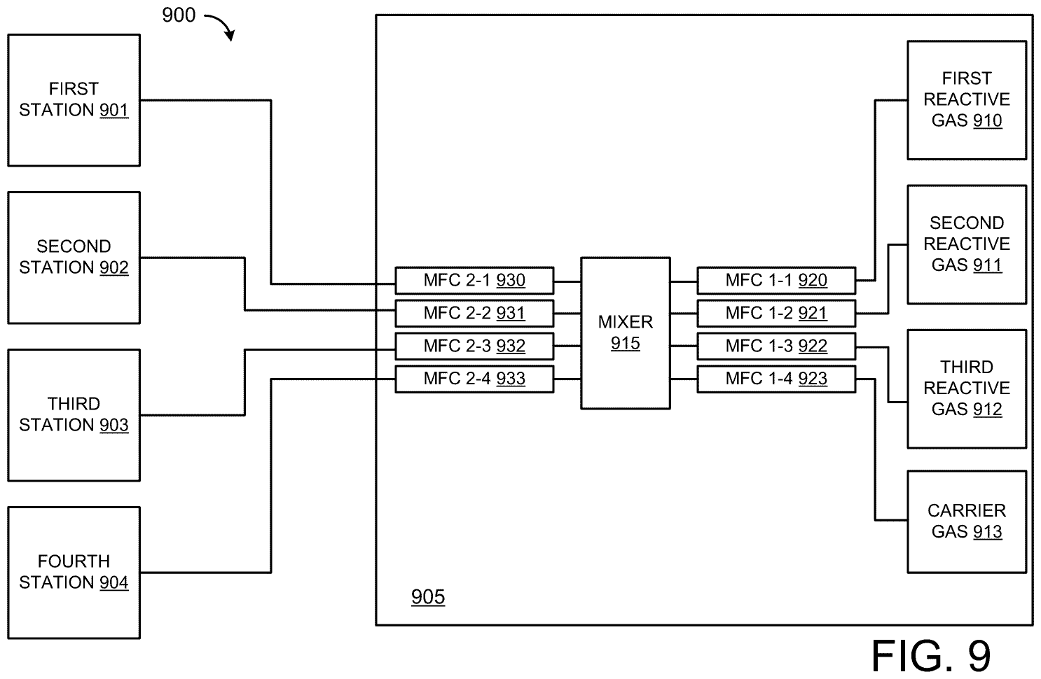

FIG. 9 schematically shows an example multi-station process tool 900 comprising mass flow controllers for flowing each gas into a mixer followed by mass flow controllers for each processing station. Multi-station process tool 900 is shown comprising four processing stations: first station 901, second station 902, third station 903, and fourth station 904.

Multi-station process tool 900 comprises gas sources 905. Gas sources 905 comprises a first reactive gas 910, a second reactive gas 911, a third reactive gas 912, and a carrier gas 913. Each reactive gas is flowed to an MFC, then into a mixer 915. First reactive gas 910 is coupled to MFC 1-1 920. Second reactive gas 911 is coupled to MFC 1-2 921. Third reactive gas 912 is coupled to MFC 1-3 922. Carrier gas 913 is coupled to MFC 1-4 923.

Mixer 915 directs the gas mixture to four MFCs, one for each processing station. MFC 2-1 930 provides the gas mixture to first station 901. MFC 2-2 931 provides the gas mixture to second station 902. MFC 2-3 932 provides the gas mixture to third station 903. MFC 2-4 933 provides the gas mixture to fourth station 904.

One or more additional pressurizing devices may be positioned upstream of the second set of MFCs in order to raise the pressure of the gas mixture to ensure precise flow control. In some examples, an additional MFC may be included in gas sources 905 for precise control of one or more of the reactive gases. As per multi-station process tool 800, multi-station process tool 900 allows for each station to be provided with on/off control of each gas. Comparatively, multi-station process tool 900 may afford slightly less precision in gas flow control as compared to multi-station process tool 800. However, multi-station process tool 900 also may be less expensive and less complex than multi-station process tool 800.

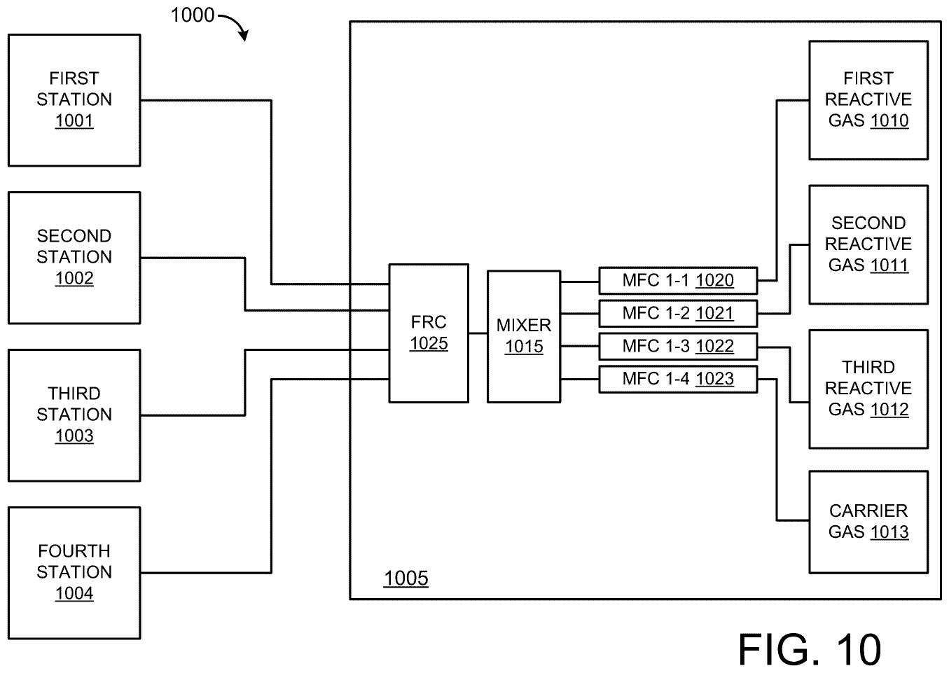

FIG. 10 schematically shows an example multi-station process tool 1000 comprising mass flow controllers for flowing each gas into a mixer followed by a flow rate controller for distributing to each processing station. Multi-station process tool 1000 is shown comprising four processing stations: first station 1001, second station 1002, third station 1003, and fourth station 1004.

Multi-station process tool 1000 further comprises gas sources 1005. Gas sources 1005 comprises a first reactive gas 1010, a second reactive gas 1011, a third reactive gas 1012, and a carrier gas 1013. Each reactive gas is flowed to an MFC, then into a mixer 1015. First reactive gas 1010 is coupled to MFC 1-1 1020. Second reactive gas 1011 is coupled to MFC 1-2 1021. Third reactive gas 1012 is coupled to MFC 1-3 1022. Carrier gas 1013 is coupled to MFC 1-4 1023.

Mixer 1015 then directs the gas mixture to FRC 1025. FRC 1025 splits the gas mixture to the four processing stations. Using an FRC instead of individual MFCs at this stage allows for flowing gas with a low pressure change, as low pressure gas can both enter and exit the FRC. As per multi-station process tool 900, an additional MFC may be included in gas sources 1005 for precise control of one or more of the reactive gases (e.g., silane).

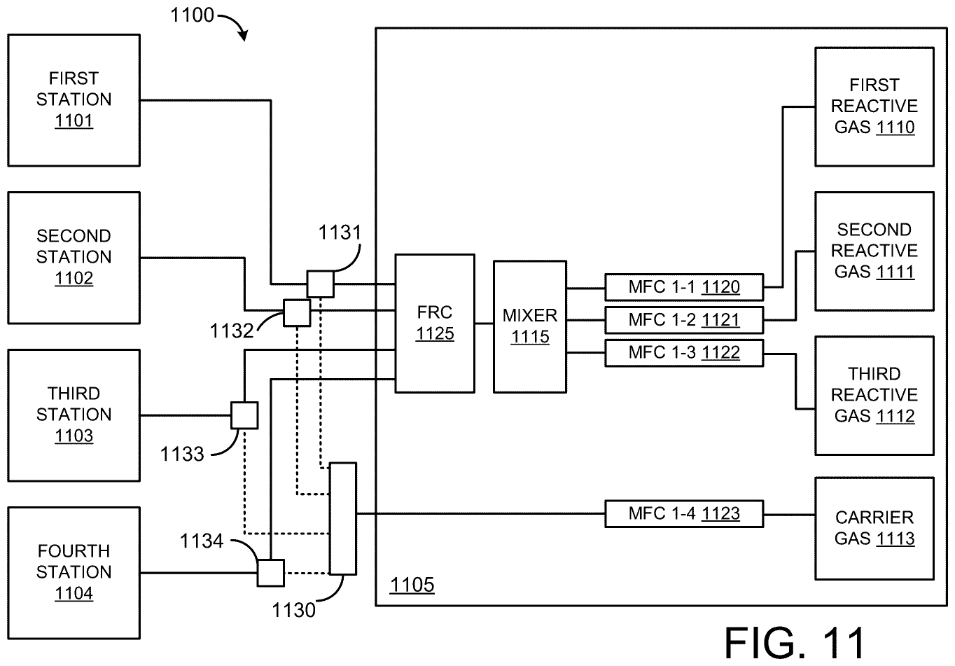

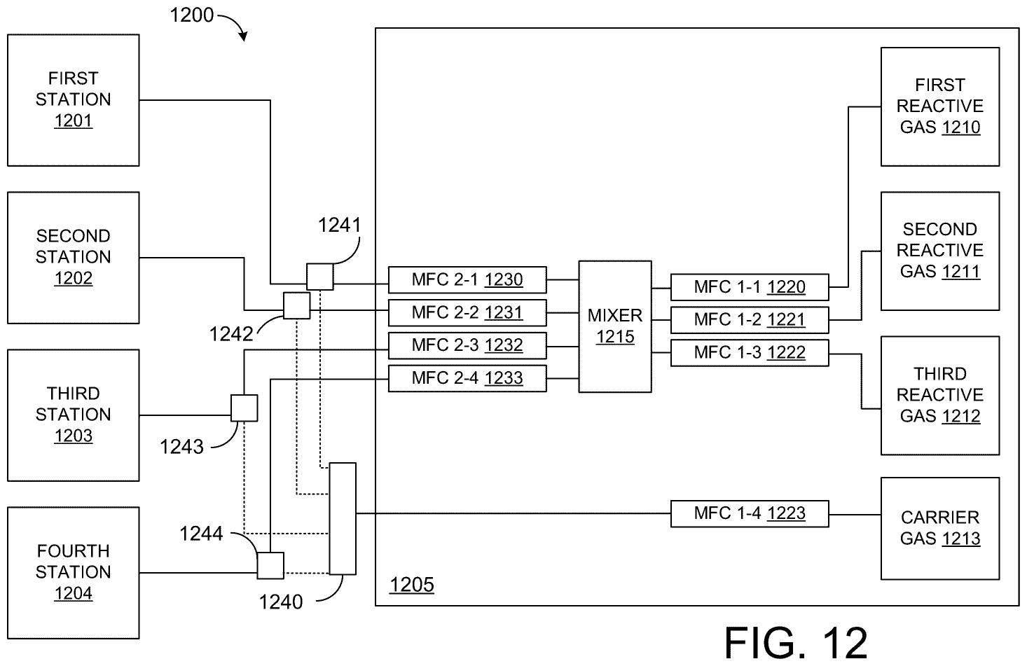

FIG. 11 schematically shows an example multi-station process tool 1100 comprising mass flow controllers for flowing each reactant gas into a mixer followed by a flow rate controller for distributing to each processing station via a mixer for a carrier gas. Multi-station process tool 1100 is shown comprising four processing stations: first station 1101, second station 1102, third station 1103, and fourth station 1104.

Multi-station process tool 1100 further comprises gas sources 1105. Gas sources 1105 comprises a first reactive gas 1110, a second reactive gas 1111, a third reactive gas 1112, and a carrier gas 1113. Each reactive gas is flowed to an MFC, then into a mixer 1115. First reactive gas 1110 is coupled to MFC 1-1 1120. Second reactive gas 1111 is coupled to MFC 1-2 1121. Third reactive gas 1112 is coupled to MFC 1-3 1122. Carrier gas 1113 is coupled to MFC 1-4 1123.

The reactive gas mixture is then passed to FRC 1125 which divides the mixture along four flow paths, one for each processing station. Carrier gas 1113 is flowed from MFC 1-4 1123 to a gas manifold 1130, which divides carrier gas flow into four lines. Each carrier gas line merges with a reactive gas flow path at a mixer before being passed to a processing station. Mixer 1131 directs combined gas flow to first station 1101, mixer 1132 directs combined gas flow to second station 1102, mixer 1133 directs combined gas flow to third station 1103, and mixer 1134 directs combined gas flow to fourth station 1104.

In this configuration, the reactive gases are mixed together first at relatively smaller volumes. The carrier gas is then mixed in later at a relatively higher volume. As the carrier gas concentration can be less precise, this allows for controlled mixing of the reactive gases without additional hardware to precisely mix in the carrier gas further upstream than necessary.

FIG. 12 schematically shows an example multi-station process tool 1200 comprising mass flow controllers for flowing each reactant gas into a mixer followed by mass flow controllers for distributing to each processing station via a mixer for a carrier gas. Multi-station process tool 1200 is shown comprising four processing stations: first station 1201, second station 1202, third station 1203, and fourth station 1204.

Multi-station process tool 1200 further comprises gas sources 1205. Gas sources 1205 comprise a first reactive gas 1210, a second reactive gas 1211, a third reactive gas 1212, and a carrier gas 1213. Each reactive gas is flowed to an MFC, then into a mixer 1215. First reactive gas 1210 is coupled to MFC 1-1 1220. Second reactive gas 1211 is coupled to MFC 1-2 1221. Third reactive gas 1212 is coupled to MFC 1-3 1222. Carrier gas 1213 is coupled to MFC 1-4 1223.

Mixer 1215 directs the gas mixture to four MFCs, one for each processing station. MFC 2-1 1230 provides the gas mixture to first station 1201. MFC 2-2 1231 provides the gas mixture to second station 1202. MFC 2-3 1232 provides the gas mixture to third station 1203. MFC 2-4 1233 provides the gas mixture to fourth station 1204. One or more additional pressurizing devices may be positioned upstream of the second set of MFCs in order to raise the pressure of the gas mixture to ensure precise flow control.

Carrier gas 1213 is flowed from MFC 1-4 1223 to a gas manifold 1240, which divides carrier gas flow into four lines. Each carrier gas line merges with a reactive gas flow path at a mixer before being passed to a processing station. Mixer 1241 directs combined gas flow to first station 1201, mixer 1242 directs combined gas flow to second station 1202, mixer 1243 directs combined gas flow to third station 1203, and mixer 1244 directs combined gas flow to fourth station 1204.

In any of the examples described with regard to FIGS. 8-12, the additional flow control hardware can provide additional dynamic control to adjust gas flows between process steps. Based on monitored conditions during processing (e.g., film thickness, deposition rate, etching rate, RI), flows can be adjusted (possibly via automation) between process steps. In other examples, multiple different processes can be performed on the same station consecutively, and multiple different processes can be performed on adjacent stations within the same multi-station tool.

In these examples, wide range tunability of flow is provided for each individual station. The tuning may be directed automatically, or from the user interface for the tool, without needing to shut the tool down to manually adjust and/or swap components. Further, the MFC control provides additional ability to turn off flow to a specific station.

In some embodiments, the methods and processes described herein may be tied to a computing system of one or more computing devices. In particular, such methods and processes may be implemented as a computer-application program or service, an application-programming interface (API), a library, and/or other computer-program product.

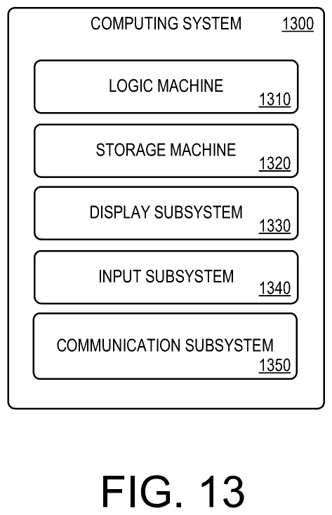

FIG. 13 schematically shows a non-limiting embodiment of a computing system 1300 that can enact one or more of the methods and processes described above. Computing system 1300 is shown in simplified form. Computing system 1300 may take the form of one or more personal computers, workstations, computers integrated with wafer processing tools, and/or network accessible server computers.

Computing system 1300 includes a logic machine 1310 and a storage machine 1320. Computing system 1300 may optionally include a display subsystem 1330, input subsystem 1340, communication subsystem 1350, and/or other components not shown in FIG. 13. Controller 120 is an example of computing system 1300.

Logic machine 1310 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1320 includes one or more physical devices configured to hold instructions executable by the logic machine to implement the methods and processes described herein. When such methods and processes are implemented, the state of storage machine 1320 may be transformed—e.g., to hold different data.

Storage machine 1320 may include removable and/or built-in devices. Storage machine 1320 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1320 may include volatile, nonvolatile, dynamic, static, read/write, read-only, random-access, sequential-access, location-addressable, file-addressable, and/or content-addressable devices.

It will be appreciated that storage machine 1320 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1310 and storage machine 1320 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1330 may be used to present a visual representation of data held by storage machine 1320. This visual representation may take the form of a graphical user interface (GUI). As the herein described methods and processes change the data held by the storage machine, and thus transform the state of the storage machine, the state of display subsystem 1330 may likewise be transformed to visually represent changes in the underlying data. Display subsystem 1330 may include one or more display devices utilizing virtually any type of technology. Such display devices may be combined with logic machine 1310 and/or storage machine 1320 in a shared enclosure, or such display devices may be peripheral display devices.

When included, input subsystem 1340 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 1350 may be configured to communicatively couple computing system 1300 with one or more other computing devices. Communication subsystem 1350 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 1300 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A system for a dry process tool, comprising:
one or more processing chambers;
two or more processing stations being positioned within the one or more processing chambers; and
a first gas source; and
a common manifold coupled to the first gas source via at least a first mass flow controller, such that the common manifold fluidly couples the first gas source to each processing station of the two or more processing stations via a corresponding flow path, each corresponding flow path comprising an adjustable flow valve.

2. The system of claim 1, wherein each adjustable flow valve is adjustable to have a highest valve flow coefficient within the corresponding flow path.

3. The system of claim 1, wherein one or more of the corresponding flow paths each comprises a fixed orifice positioned in parallel with the adjustable flow valve.

4. The system of claim 1, wherein each corresponding flow path is coupled to the common manifold via a flexible gas line, and wherein each flow path comprises one or more components that are configured to be movable relative to a processing chamber of a respective processing station.

5. The system of claim 1, wherein each flow path further comprises an on/off flow valve upstream of the adjustable flow valve.

6. The system of claim 5, wherein each flow path further comprises a filter upstream of the on/off flow valve.

7. The system of claim 1, further comprising a second gas source connected to the common manifold via a second mass flow controller.

8. The system of claim 1, further comprising, for each processing station, a mixer positioned within the flow path upstream of the processing station, the mixer for each processing station coupled via a second corresponding flow path to a second common manifold, the second common manifold coupled to a second gas source, the second gas source configured to provide a different gas composition than the first gas source.

9. The system of claim 8, wherein the second corresponding flow path comprises an on/off flow valve in series with one or more of a fixed orifice or a second adjustable flow valve.

10. The system of claim 1, wherein the one or more processing chambers comprises a plurality of processing chambers, and wherein each processing station of the two or more processing stations is positioned within a separate processing chamber of the plurality of processing chambers.

11. The system of claim 1, wherein at least two of the two or more processing stations are positioned within a shared processing chamber of the one or more processing chambers.

12. The system of claim 1, wherein the dry process tool comprises a chemical vapor deposition tool.

13. The system of claim 1, wherein the dry process tool comprises an atomic layer deposition tool.

14. The system of claim 1, wherein the dry process tool comprises a dry-etching tool.

15. The system of claim 1, wherein the adjustable flow valve comprises an automated valve.

16. A method for calibrating a multi-station processing system, comprising:
setting a chamber pressure of a common gas source to a calibration gas pressure; and
for each station of the multi-station processing system coupled to the common gas source:
closing gas flow to one or more other stations;
flowing gas from the common gas source to a station being adjusted;
sensing an upstream gas pressure at the gas source; and
when the upstream gas pressure is not within a threshold difference from a predetermined gas pressure, then adjusting an adjustable valve in a flow path to the station being adjusted to set the upstream gas pressure to a pressure within the threshold difference from the predetermined gas pressure.

17. The method of claim 16, wherein calibrating the multi-station processing system is performed in response to a changed consumable component in one or more stations.

18. A method for calibrating a multi-station processing system, comprising:
balancing gas flow for at least a first station and a second station of the multi-station processing system by adjusting a first adjustable valve in a first flow path of the first station and adjusting a second adjustable valve in a second flow path of the second station;
sensing a compensatable hardware disparity in the first station;
adjusting gas flow for the first station by adjusting a setting of the first adjustable valve in the flow path of the first station; and
maintaining a setting of the second adjustable valve.

19. The method of claim 18, wherein adjusting gas flow for the first station comprises increasing gas flow by increasing a size of an aperture of the first adjustable valve.

20. The method of claim 18, wherein adjusting gas flow for the first station comprises decreasing gas flow by decreasing a size of an aperture of the first adjustable valve.

21-29. (canceled)
